(19) United States
(12) Patent Application Publication
(10) Pub. No.: US 2026/0322382 A1
(43) Pub. Date: Oct. 15, 2026

(54) FAIL-SAFE IO CIRCUIT

(71) Applicant: DB HiTek Co., Ltd., Seoul (KR)

(72) Inventors: Sangmok LEE, Bucheon-si (KR); Hyunsub JUNG, Bucheon-si (KR); Seunghyun KOO, Bucheon-si (KR); Jung-eun LEE, Bucheon-si (KR)

(73) Assignee: DB HiTek Co., Ltd., Seoul (KR)

(21) Appl. No.: 19/272,859

(22) Filed: Jul. 17, 2025

(30) Foreign Application Priority Data
Apr. 9, 2025 (KR) 10-2025-0045929

(51) Int. Cl. H03K 19/003; H03K 19/00; H03K 19/0185

(52) U.S. Cl. CPC H03K 19/00361; H03K 19/0013; H03K 19/00315; H03K 19/018528

(57) ABSTRACT

A fail-safe input/output circuit is provided. A fail-safe input/output circuit comprising: a pad that is an output end of the fail-safe input/output circuit; a pad drive circuit connected to the pad; and a first control circuit connected to the pad drive circuit and a power supply voltage, wherein the first control circuit comprises: a first sub-circuit connected to a first drive node of the pad drive circuit via a first node; and a second sub-circuit connected to the first sub-circuit via a second node and connected to the power supply voltage, and wherein the second sub-circuit comprises: a first transistor having one end connected to the power supply voltage and the other end connected to the second node; and a second transistor controlled by the power supply voltage and having one end connected to a gate of the first transistor and the other end connected to the pad.

### CROSS-REFERENCE TO RELATED APPLICATION

This application claims priority under 35 U.S.C § 119 to Korean Patent Application No. 10-2025-0045929, filed Apr. 9, 2025, in the Korean Intellectual Property Office, the entire contents of which are hereby incorporated by reference.

### Technical Field

The disclosure relates to a fail-safe input/output (IO) circuit having a fail-safe function.

### Description of the Related Art

The content set forth in this section merely provides background information on the present embodiments and does not constitute prior art.

In the field of applied products that use batteries (e.g., mobile and portable devices, etc.), power consumption can be a key factor in competitiveness. Recently, in order to reduce the leakage current occurring in the standby state, attempts have been made to further reduce power consumption by turning off the internal logic power, which accounts for most of the leakage current, or by turning off the input/output power as well.

### BRIEF SUMMARY

Various embodiments of the present disclosure are directed to fail-safe input/output (I/O) interface technologies operable during a power-off state, in which both internal logic power and I/O power are disabled (e.g., turned off). Such power-safe I/O technologies are configured to mitigate or prevent interface errors that may otherwise arise during the power-off state or during transitions into the power-off state.

Additional embodiments are directed to circuit architectures and techniques for suppressing or eliminating leakage current in power-safe I/O circuits, thereby enabling reliable implementation of the power-safe I/O functionality described herein.

Various embodiments of the present disclosure provide a fail-safe input/output circuit capable of reducing leakage current.

The technical benefits of the present disclosure are not limited to the benefits mentioned above, and other advantages of the present disclosure that have not been mentioned can be understood by the following description and will be more clearly understood by the embodiments of the present disclosure. Furthermore, it will be readily appreciated that the advantages of the present disclosure can be realized by the means set forth in the claims and combinations thereof.

The fail-safe input/output circuit of the present disclosure can prevent leakage current that may occur in the power-off mode by including the control circuits that control the circuits connected directly to the pad.

According to some aspects of the disclosure, a fail-safe input/output circuit comprising: a pad that is an output end of the fail-safe input/output circuit; a pad drive circuit connected to the pad; and a first control circuit connected to the pad drive circuit and a power supply voltage, wherein the first control circuit comprises: a first sub-circuit connected to a first drive node of the pad drive circuit via a first node; and a second sub-circuit connected to the first sub-circuit via a second node and connected to the power supply voltage, and wherein the second sub-circuit comprises: a first transistor having one end connected to the power supply voltage and the other end connected to the second node; and a second transistor controlled by the power supply voltage and having one end connected to a gate of the first transistor and the other end connected to the pad.

According to some aspects, wherein the one end of the first transistor is connected to the power supply voltage, and is connected to the power supply voltage by being connected tovia a floating well connected to the power supply voltage, and a gate of the second transistor is connected to the power supply voltage, and is connected to the power supply voltage by being connected to via the floating well.

According to some aspects, wherein the first drive node, the floating well, and the pad are at the same voltage when the power supply voltage is off.

According to some aspects, wherein the floating well is connected to a floating well control circuit, and wherein the floating well control circuit: causes a voltage of the pad to be applied to the floating well when the power supply voltage is off, and causes the power supply voltage to be applied to the floating well when the power supply voltage is on.

According to some aspects, wherein the floating well control circuit comprises: a first floating well transistor having one end connected to the power supply voltage and the other end connected to the floating well; a second floating well transistor having one end connected to the floating well and the other end connected to the pad; a third floating well transistor having one end connected to a gate of the first floating well transistor via a floating well node and the other end connected to a ground voltage; and a fourth floating well transistor having one end connected to the gate of the first floating well transistor via the floating well node and the other end connected to the pad, and wherein a gate of the third floating well transistor is connected to the power supply voltage, a gate of the fourth floating well transistor is connected to the power supply voltage via the floating well, and a floating well control signal is output via the floating well node.

According to some aspects, further comprising: a second control circuit, which is connected to a second drive node different from the first drive node of the pad drive circuit and into which the control signal is input, wherein the second control circuit applies a ground voltage to the second drive node when the power supply voltage is off.

According to some aspects, wherein the second sub-circuit further comprises a third transistor controlled by the power supply voltage and having one end connected to the one end of the second transistor.

According to some aspects, wherein the pad drive circuit comprises: a fourth transistor having one end connected to the power supply voltage and including a gate connected to the first drive node; a fifth transistor controlled by the power supply voltage and having one end connected to the first drive node and the other end connected to the pad; and a sixth transistor having one end connected to the other end of the fourth transistor.

According to some aspects, wherein the first control circuit further comprises a third sub-circuit connected to the first sub-circuit and controlled by the power supply voltage, the first sub-circuit comprises a seventh transistor having one end connected to the first node, the third sub-circuit is connected to a gate of the seventh transistor, and the seventh transistor is turned off by the third sub-circuit when the power supply voltage is off.

According to some aspects, further comprising: a second control circuit connected to a second drive node different from the first drive node of the pad drive circuit, wherein the second control circuit applies a ground voltage to the second drive node when the power supply voltage is off.

Aspects of the disclosure are not limited to those mentioned above and other objects and advantages of the disclosure that have not been mentioned can be understood by the following description and will be more clearly understood according to embodiments of the disclosure. In addition, it will be readily understood that the objects and advantages of the disclosure can be realized by the means and combinations thereof set forth in the claims.

In addition to the foregoing description, specific effects of the present disclosure will be stated together while describing specific details for implementing the present disclosure below.

### BRIEF DESCRIPTION OF THE SEVERAL VIEWS OF THE DRAWINGS

FIG. 1 is a diagram for describing a fail-safe input/output circuit according to some embodiments of the present disclosure.

FIG. 2 is a detailed diagram of the circuit diagram of FIG. 1.

FIG. 3 is a diagram for describing a floating well control circuit according to some embodiments for applying a voltage to the floating well of FIG. 2.

FIG. 4 is a diagram for describing a fail-safe input/output circuit according to some embodiments of the present disclosure.

FIG. 5 is a detailed diagram of the circuit diagram of FIG. 4.

FIGS. 6 and 7 are diagrams for describing a fail-safe input/output circuit according to some embodiments of the present disclosure.

FIG. 8 is a detailed diagram of the circuit diagrams of FIGS. 6 and 7.

FIG. 9 is a diagram for describing a fail-safe input/output circuit according to some embodiments of the present disclosure.

FIG. 10 is a diagram for describing a floating well control circuit according to some embodiments of the present disclosure.

### DETAILED DESCRIPTION

As used herein, the term "connected" is intended to have the broadest possible meaning. Specifically, the phrase "A is connected to B" encompasses both a direct connection—where no intervening components or elements are present—and an indirect connection, where one or more intermediate components or elements exist between A and B. In other words, "A is connected to B" includes both direct physical or electrical coupling and indirect coupling through one or more intervening components. Unless explicitly stated otherwise, these terms do not require direct physical or electrical contact. The term "coupled" and "in contact" should be interpreted in the same manner.

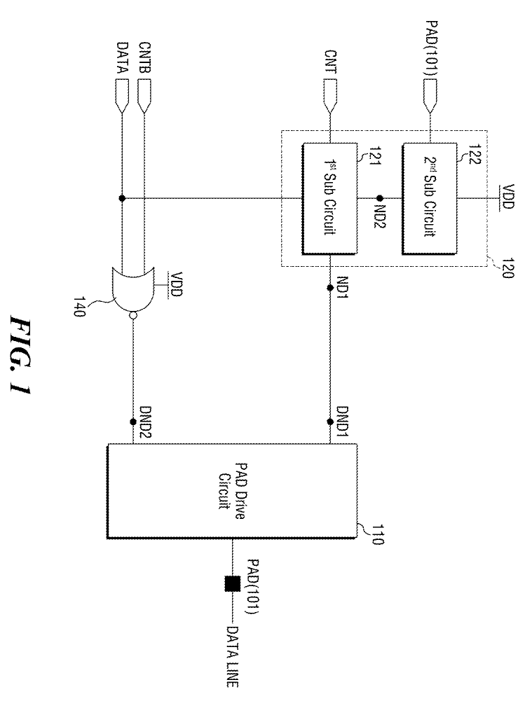

Hereinafter, a fail-safe input/output (IO) circuit according to some embodiments of the present disclosure will be described with reference to FIGS. 1, 2, 3, and 4.

FIG. 1 is a diagram for describing a fail-safe input/output circuit according to some embodiments of the present disclosure.

Referring to FIG. 1, the fail-safe input/output circuit according to some embodiments of the present disclosure may include a pad 101, a pad drive circuit 110, a first control circuit 120, and a NOR logic circuit 140.

The pad 101 may be an output end of the fail-safe input/output circuit. The pad 101 may be connected to a data line DATA LINE.

The pad drive circuit 110 may be connected to the pad 101. The pad drive circuit 110 may control the voltage of the pad 101 so that the voltage of the pad 101 remains constant in the power-off mode and the power-on mode.

The pad drive circuit 110 may be connected to the first control circuit 120 via a first drive node DND1. For example, by having the first drive node DND1 and a first node ND1 connected to each other, the first control circuit 120 and the pad drive circuit 110 may be connected to each other. The pad drive circuit 110 may be connected to the NOR logic circuit 140 via a second drive node DND2.

The first control circuit 120 may be connected to the pad drive circuit 110 and a power supply voltage VDD. The first control circuit 120 may receive the power supply voltage VDD, the voltage of the pad 101, a first control signal CNT, and a data signal DATA as inputs, and may output a voltage to the first node ND1. Due to the first control circuit 120, the first drive node DND1 and the pad 101 can maintain the same voltage in the power-off mode, which is a state where the power supply voltage is off.

The first control signal CNT and the data signal DATA may be signals input from the outside.

The first control circuit 120 may include a first sub-circuit 121 and a second sub-circuit 122. The first sub-circuit 121 may be connected to the first drive node DND1 of the pad drive circuit 110 via the first node ND1. The second sub-circuit 122 may be connected to the first sub-circuit 121 via a second node ND2 and may then be connected to the power supply voltage VDD.

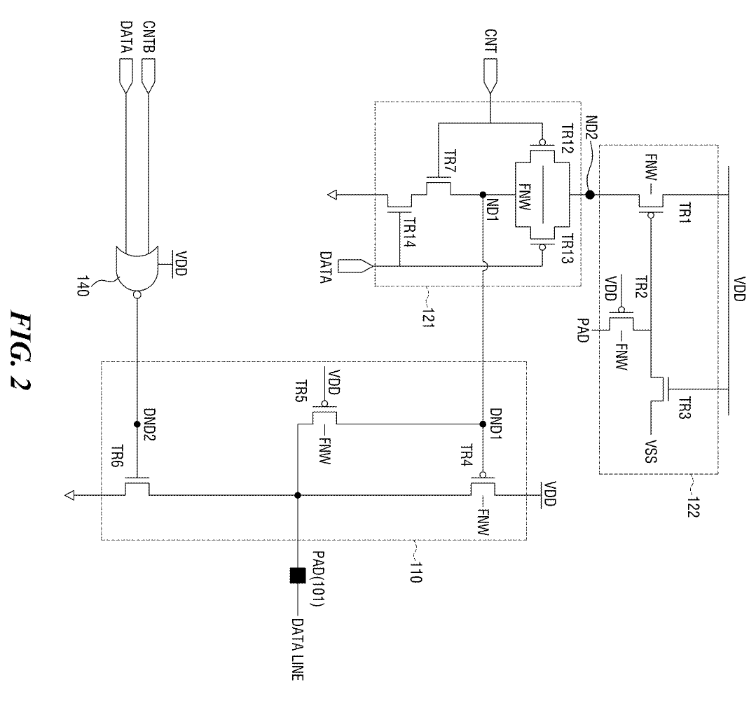

Details on the first control circuit 120 will be described later with reference to FIG. 2.

The NOR logic circuit 140 may be connected to the second drive node DND2 of the pad drive circuit 110. The NOR logic circuit 140 may receive the power supply voltage VDD, a second control signal CNTB, and the data signal DATA as inputs. The second control signal CNTB may be a signal input from the outside.

FIG. 2 is a detailed diagram of the circuit diagram of FIG. 1.

Referring to FIGS. 1 and 2, the second sub-circuit 122 may include a first transistor TR1, a second transistor TR2, and a third transistor TR3.

One end of the first transistor TR1 may be connected to the power supply voltage VDD, and the other end may be connected to the second node ND2. One end of the second transistor TR2 may be connected to the gate of the first transistor TR1, and the other end may be connected to the pad 101. The gate of the second transistor TR2 may be connected to the power supply voltage VDD, and the second transistor TR2 may thus be controlled by the power supply voltage VDD. One end of the third transistor TR3 may be connected to one end of the second transistor TR2, and the other end may be connected to a ground voltage VSS. The gate of the third transistor TR3 may be connected to the power supply voltage VDD, and the third transistor TR3 may thus be controlled by the power supply voltage VDD.

The first transistor TR1 and the second transistor TR2 may be PMOS transistors, and the third transistor TR3 may be an NMOS transistor.

The first sub-circuit 121 may include a twelfth transistor TR12, a thirteenth transistor TR13, a seventh transistor TR7, and a fourteenth transistor TR14.

One end of the twelfth transistor TR12 may be connected to the second node ND2, and the other end may be connected to the first node ND1. The gate of the twelfth transistor TR12 may receive the first control signal CNT as input. The twelfth transistor TR12 may be controlled by the first control signal CNT. One end of the thirteenth transistor TR13 may be connected to the second node ND2, and the other end may be connected to the first node ND1. The thirteenth transistor TR13 and the twelfth transistor TR12 may be connected in parallel. The gate of the thirteenth transistor TR13 may receive the data signal DATA as input. The thirteenth transistor TR13 may be controlled by the data signal DATA. One end of the seventh transistor TR7 may be connected to the first node ND1. The gate of the seventh transistor TR7 may receive the first control signal CNT as input. The seventh transistor TR7 may be controlled by the first control signal CNT. One end of the fourteenth transistor TR14 may be connected to the other end of the seventh transistor TR7, and the other end may be connected to the ground voltage. The gate of the fourteenth transistor TR14 may receive the data signal DATA as input. The fourteenth transistor TR14 may be controlled by the data signal DATA.

The pad drive circuit 110 may include a fourth transistor TR4, a fifth transistor TR5, and a sixth transistor TR6.

One end of the fourth transistor TR4 may be connected to the power supply voltage VDD, and the other end may be connected to the pad 101. The gate of the fourth transistor TR4 may be connected to the first drive node DND1, and the fourth transistor TR4 may thus be controlled by a voltage applied to the first drive node DND1. One end of the fifth transistor TR5 may be connected to the first drive node DND1, and the other end may be connected to the pad 101. The gate of the fifth transistor TR5 may be connected to the power supply voltage VDD, and the fifth transistor TR5 may thus be controlled by the power supply voltage VDD. One end of the sixth transistor TR6 may be connected to the pad 101, and the other end may be connected to the ground voltage. The gate of the sixth transistor TR6 may be connected to the second drive node DND2, and the sixth transistor TR6 may thus be controlled by a voltage applied to the second drive node DND2.

The fourth transistor TR4 and the fifth transistor TR5 may be PMOS transistors, and the sixth transistor TR6 may be an NMOS transistor.

In some embodiments, the power supply voltage VDD may be connected to floating wells FNW. The floating wells FNW may be wells in a floating state disposed in a substrate on which circuits (e.g., the pad drive circuit 110 and the first control circuit 120) are formed. The floating wells FNW may be, for example, an n-type. One end of the first transistor TR1, the gate of the second transistor TR2, one end of the fourth transistor TR4, and the gate of the fifth transistor TR5 may be directly connected to the floating wells FNW, and may thereby be connected to the power supply voltage VDD.

In the power-on mode (i.e., VD V(volts) is applied to the power supply voltage VDD), if the first control signal CNT is low, the power supply voltage VDD may be applied to the first drive node DND1 regardless of the state of the data signal DATA, causing the fourth transistor TR4 to be turned off. In the power-on mode, if the first control signal CNT is high, the power supply voltage VDD may be applied to the first drive node DND1 to thereby cause the fourth transistor TR4 to be turned on when the data signal DATA is low. In the power-on mode, if the first control signal CNT is high, 0 V (volts) may be applied to the first drive node DND1 to thereby cause the fourth transistor TR4 to be turned on and the voltage of the pad 101 to be VD V (volts) when the data signal DATA is high.

In the power-off mode (i.e., 0 V is applied to the power supply voltage), when the voltage of the pad 101 is equal to VD V, the voltage of the node of the floating well FNW rises to VD V. At this time, since 0 V is applied to the power supply voltage VDD, the fifth transistor TR5 may be turned on, causing VD V, which is the voltage applied to the pad 101, to be applied to the first drive node DND1. Further, the third transistor TR3 may be turned off and thus block the ground voltage VSS, and the second transistor TR2 may be turned on and thus apply the voltage (i.e., VD V) applied to the pad 101 to the gate of the first transistor TR1, thereby turning off the first transistor TR1. That is, according to the fail-safe input/output circuit in accordance with the embodiment of the present disclosure, the first drive node DND1 can be maintained to be the same as the voltage applied to the pad 101, and thus, the first drive node DND1, the pad 101, and the floating well FNW can all be at the same voltage in the power-off mode in which the power supply voltage is off. By having VD V applied to the first drive node DND1, the fourth transistor TR4 can be turned off. Thereby, the leakage current path flowing from the pad 101 to the power supply voltage VDD via the fourth transistor TR4 can be cut off.

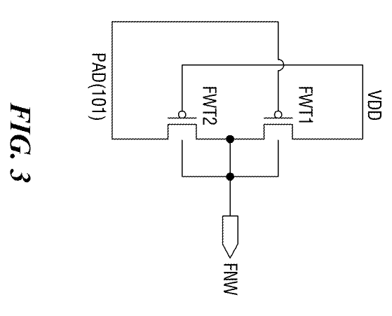

FIG. 3 is a diagram for describing a floating well control circuit according to some embodiments for applying a voltage to the floating well of FIG. 2.

Referring to FIGS. 2 and 3, the floating well control circuit may cause the voltage of the pad 101 to be applied to the floating wells FNW when in the power-off mode in which the power supply voltage is off. Further, the floating well control circuit may cause the power supply voltage to be applied to the floating wells FNW when in the power-on mode in which the power supply voltage is on.

The floating well control circuit may include a first floating well transistor FWT1 and a second floating well transistor FWT2. The first floating well transistor FWT1 and the second floating well transistor FWT2 may be PMOS transistors.

One end of the first floating well transistor FWT1 may be connected to the power supply voltage VDD, and the other end may be connected to the node of the floating well FNW, which is the output end. The gate of the first floating well transistor FWT1 may be connected to the pad 101, and the first floating well transistor FWT1 may thus be controlled by a voltage applied to the pad 101. One end of the second floating well transistor FWT2 may be connected to the node of the floating well FNW, which is the output end, and the other end may be connected to the pad 101. The gate of the second floating well transistor FWT2 may be connected to the power supply voltage VDD, and the second floating well transistor FWT2 may thus be controlled by the power supply voltage VDD.

In the power-on mode, the first floating well transistor FWT1 may be turned on and the second floating well transistor FWT2 may be turned off, and thus, the power supply voltage VDD may be output to the node of the floating well FNW.

In the power-off mode, the first floating well transistor FWT1 may be turned off and the second floating well transistor FWT2 may be turned on, and thus, the voltage of the pad 101 may be output to the node of the floating well FNW.

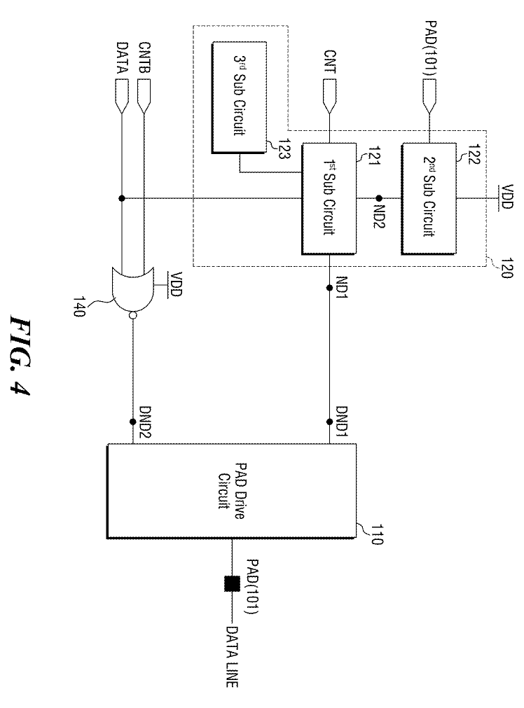

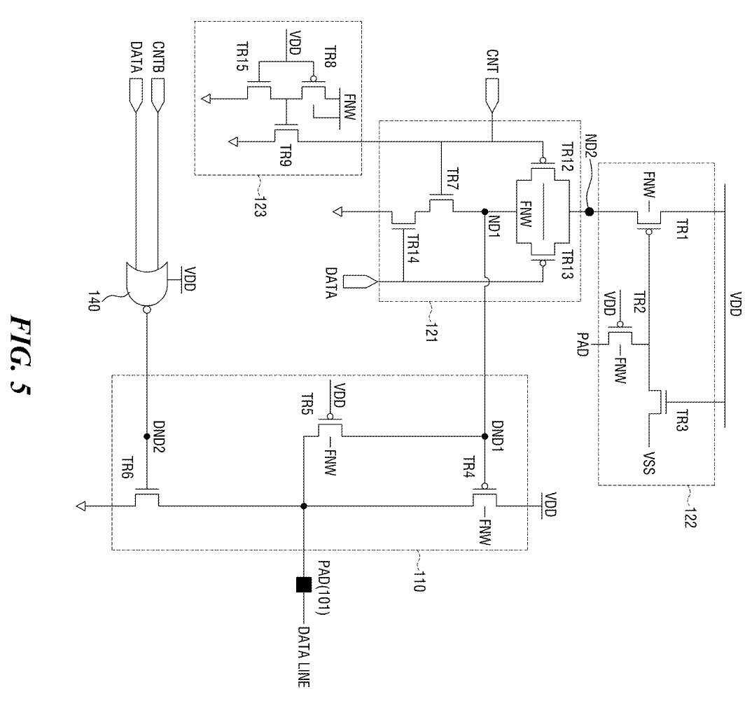

In the following, a fail-safe input/output circuit according to some embodiments of the present disclosure will be described with reference to FIGS. 4 and 5. For clarity of description, any parts that overlap with what has been described above will be simplified or omitted.

FIG. 4 is a diagram for describing a fail-safe input/output circuit according to some embodiments of the present disclosure. FIG. 5 is a detailed diagram of the circuit diagram of FIG. 4.

Referring to FIGS. 4 and 5, the fail-safe input/output circuit according to some embodiments of the present disclosure may further include a third sub-circuit 123.

The third sub-circuit 123 may be connected to the first sub-circuit 121 and may be controlled by the power supply voltage VDD. The third sub-circuit 123 may be connected to the gate of the seventh transistor TR7 of the first sub-circuit 121.

The third sub-circuit 123 may include an eighth transistor TR8, a ninth transistor TR9, and a fifteenth transistor TR15.

One end of the eighth transistor TR8 may be connected to a floating well FNW. The gate of the eighth transistor TR8 may be connected to the power supply voltage VDD, and the eighth transistor TR8 may thus be controlled by the power supply voltage VDD. One end of the fifteenth transistor TR15 may be connected to the other end of the eighth transistor TR8, and the other end may be connected to the ground voltage. The gate of the fifteenth transistor TR15 may be connected to the power supply voltage VDD, and the fifteenth transistor TR15 may thus be controlled by the power supply voltage VDD. One end of the ninth transistor TR9 may be connected to the gate of the seventh transistor TR7 of the first sub-circuit 121, and the other end may be connected to the ground voltage. The gate of the ninth transistor TR9 may be connected to the other end of the eighth transistor TR8 and one end of the fifteenth transistor TR15.

In the power-on mode, as the eighth transistor TR8 is turned off and the fifteenth transistor TR15 is turned on, the ground voltage is applied to the gate of the ninth transistor TR9, and thus, the ninth transistor TR9 is turned off, thereby not affecting the first control signal CNT.

In the power-off mode in which the power supply voltage VDD is off, the seventh transistor TR7 may be turned off by the third sub-circuit 123. In the power-off mode, when the voltage of the pad 101 is equal to VD V (volts), the voltage of the floating well FNW is also equal to VD V (volts), the eighth transistor TR8 is turned on, and thus, VD V (volts) is applied to the gate of the ninth transistor TR9, causing the ninth transistor TR9 to be turned on as well. Thereby, the ground voltage is applied to the gate of the seventh transistor TR7, and the seventh transistor TR7 is thus turned off. As a result, the first control signal CNT remains low more stably in the power-off mode, and the leakage current path flowing from the first drive node DND1 to the ground voltage via the seventh transistor TR7 and the fourteenth transistor TR14 can be cut off.

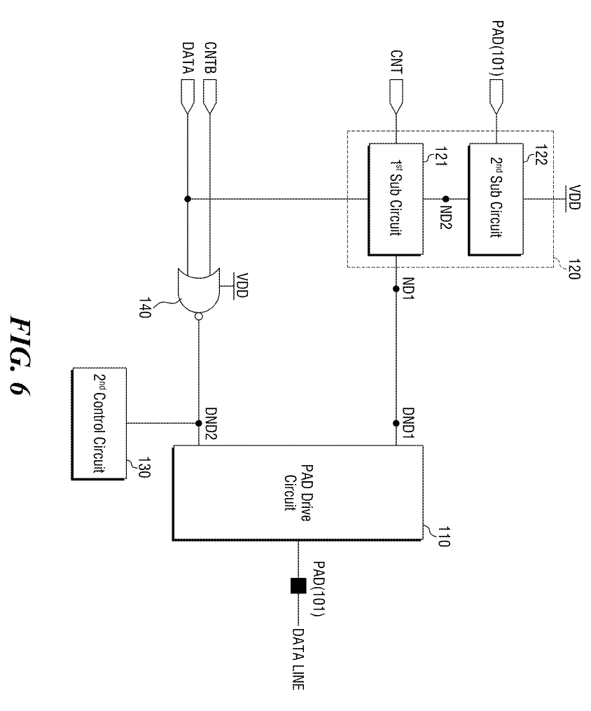

In the following, a fail-safe input/output circuit according to some embodiments of the present disclosure will be described with reference to FIGS. 6, 7, and 8. For clarity of description, any parts that overlap with what has been described above will be simplified or omitted.

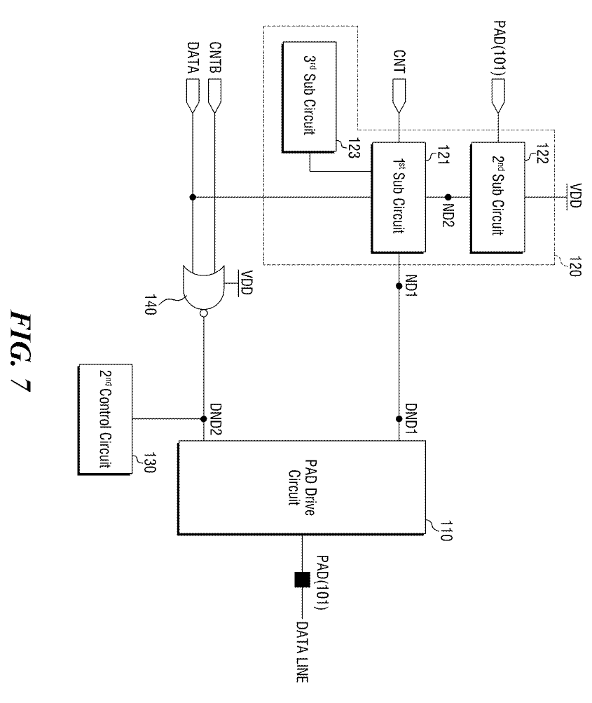

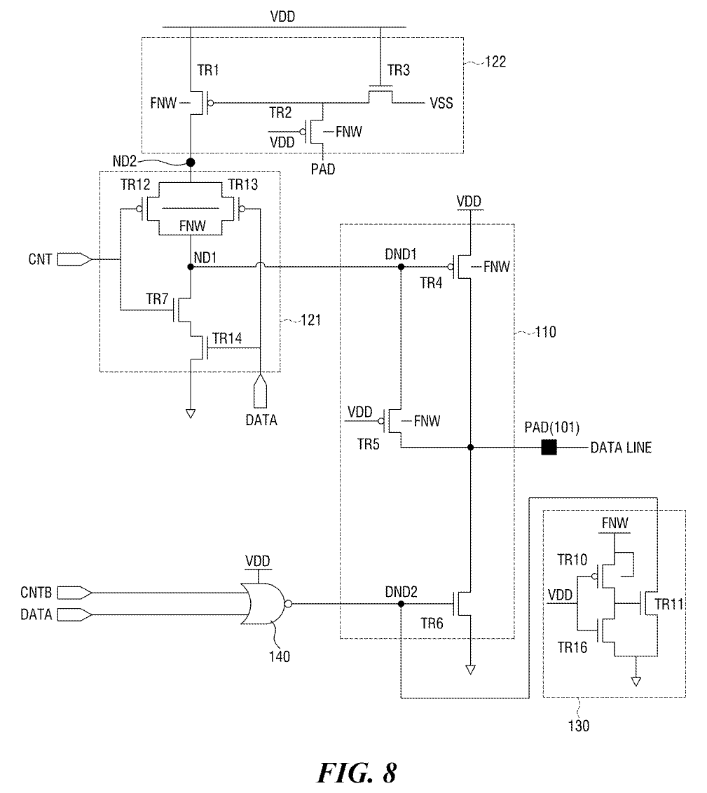

FIGS. 6 and 7 are diagrams for describing a fail-safe input/output circuit according to some embodiments of the present disclosure. FIG. 8 is a detailed diagram of the circuit diagrams of FIGS. 6 and 7.

Referring to FIGS. 6 and 7, the fail-safe input/output circuit according to some embodiments of the present disclosure may further include a second control circuit 130.

The second control circuit 130 may be connected to the second drive node DND2.

The second control circuit 130 may be connected to the second drive node DND2 in a state of not including the third sub-circuit 123 as shown in FIG. 6, or may be connected to the second drive node DND2 in a state of including the third sub-circuit 123 as shown in FIG. 7.

In the following, the detailed diagram of the second control circuit 130 will be described with reference to FIG. 6, but it is a matter of course that the description of the detailed diagram of the second control circuit 130 may also be applied to the circuit diagram of FIG. 7.

Referring to FIG. 8, the second control circuit 130 may include a tenth transistor TR10, an eleventh transistor TR11, and a sixteenth transistor TR16.

One end of the tenth transistor TR10 may be connected to a floating well FNW. The gate of the tenth transistor TR10 may be connected to the power supply voltage VDD, and the tenth transistor TR10 may thus be controlled by the power supply voltage VDD. One end of the sixteenth transistor TR16 may be connected to the other end of the tenth transistor TR10, and the other end may be connected to the ground voltage. The gate of the sixteenth transistor TR16 may be connected to the power supply voltage VDD, and the sixteenth transistor TR16 may thus be controlled by the power supply voltage VDD. One end of the eleventh transistor TR11 may be connected to the second drive node DND2, and the other end may be connected to the ground voltage. The gate of the eleventh transistor TR11 may be connected to the other end of the tenth transistor TR10 and one end of the sixteenth transistor TR16.

In the power-on mode, as the tenth transistor TR10 may be turned off and the sixteenth transistor TR16 may be turned on, the ground voltage may be applied to the gate of the eleventh transistor TR11, causing the ninth transistor TR9 to be turned off.

In the power-off mode in which the power supply voltage VDD is off, the ground voltage may be applied to the second drive node DND2 by the second control circuit 130. In the power-off mode, when the voltage of the pad 101 is equal to VD V (volts), the voltage of the floating well FNW is also equal to VD V (volts), the tenth transistor TR10 is turned on, and thus, VD V (volts) is applied to the gate of the eleventh transistor TR11, causing the eleventh transistor TR11 to be turned on as well. Thereby, the ground voltage may be applied to the second drive node DND2. By having the ground voltage applied to the second drive node DND2, the voltage rise of the parasitic capacitor formed between the second drive node DND2 and one end of the sixth transistor TR6 can be pulled down, thereby cutting off the leakage current path flowing to the ground voltage via the sixth transistor TR6.

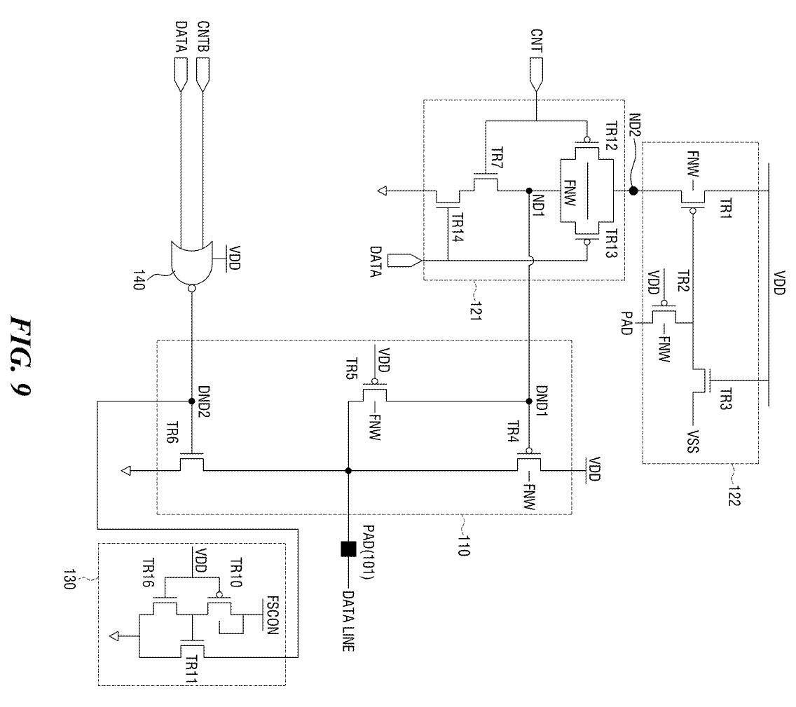

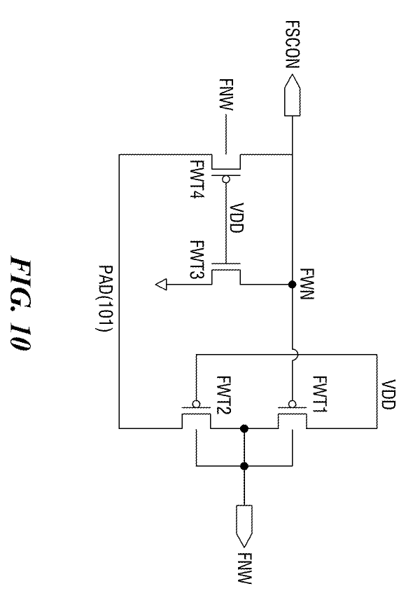

In the following, a fail-safe input/output circuit according to some embodiments of the present disclosure will be described with reference to FIGS. 9 and 10. For clarity of description, any parts that overlap with what has been described above will be simplified or omitted.

FIG. 9 is a diagram for describing a fail-safe input/output circuit according to some embodiments of the present disclosure. FIG. 10 is a diagram for describing a floating well control circuit according to some embodiments of the present disclosure.

Referring to FIGS. 9 and 10, the second control circuit 130 may receive a floating well control signal FSCON as input.

The floating well control signal FSCON may be a signal output from an output node OND, which is the output end of the floating well control circuit.

The floating well control circuit may include a first floating well transistor FWT1, a second floating well transistor FWT2, a third floating well transistor FWT3, and a fourth floating well transistor FWT4. The first floating well transistor FWT1, the second floating well transistor FWT2, and the fourth floating well transistor FWT4 may be PMOS transistors, and the third floating well transistor FWT3 may be an NMOS transistor.

One end of the first floating well transistor FWT1 may be connected to the power supply voltage VDD, and the other end may be connected to the node of the floating well FNW. The gate of the first floating well transistor FWT1 may be connected to the output node OND. One end of the second floating well transistor FWT2 may be connected to the node of the floating well FNW, and the other end may be connected to the pad 101. The gate of the second floating well transistor FWT2 may be connected to the power supply voltage VDD, and the second floating well transistor FWT2 may thus be controlled by the power supply voltage VDD.

One end of the third floating well transistor FWT3 may be connected to the output node OND, and the other end may be connected to the ground voltage. The gate of the third floating well transistor FWT3 may be connected to the power supply voltage VDD, and the third floating well transistor FWT3 may thus be controlled by the power supply voltage VDD. One end of the fourth floating well transistor FWT4 may be connected to the output node OND, and the other end may be connected to the pad 101. The gate of the fourth floating well transistor FWT4 may be connected to the power supply voltage VDD, and the fourth floating well transistor FWT4 may thus be controlled by the power supply voltage VDD. By being directly connected to the floating well FNW, the gate of the fourth floating well transistor FWT4 may be connected to the power supply voltage VDD connected to the floating well FNW.

The floating well control circuit may turn on the first floating well transistor FWT1 in the power-on state by having the third floating well transistor FWT3 turned on and the ground voltage applied to the gate of the first floating well transistor FWT1. Thereby, the power supply voltage VDD can be continuously applied to the floating well FNW, and the stability of the transistors (e.g., PMOS transistors) connected to the node of the floating well FNW can thus be secured.

The floating well control circuit may apply the voltage of the pad 101 to the floating well FNW by having the second floating well transistor FWT2 turned on in the power-off state. The third floating well transistor FWT3 may be turned off, the fourth floating well transistor FWT4 may be turned on, and thus, the voltage of the pad 101 may be applied to the output node OND, which is the gate of the first floating well transistor FWT1, thereby cutting off the leakage current path flowing from the pad 101 to the power supply voltage VDD. As a result, the voltage of the floating well FNW can be allowed to rise stably to the voltage of the pad 101.

While the inventive concept has been particularly shown and described with reference to exemplary embodiments thereof, it will be understood by those of ordinary skill in the art that various changes in form and details may be made therein without departing from the spirit and scope of the inventive concept as defined by the following claims. It is therefore desired that the embodiments be considered in all respects as illustrative and not restrictive, reference being made to the appended claims rather than the foregoing description to indicate the scope of the disclosure.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A fail-safe input/output circuit comprising:
a pad that is an output end of the fail-safe input/output circuit;
a pad drive circuit connected to the pad; and
a first control circuit connected to the pad drive circuit and a power supply voltage,
wherein the first control circuit comprises:
a first sub-circuit connected to a first drive node of the pad drive circuit via a first node; and
a second sub-circuit connected to the first sub-circuit via a second node and connected to the power supply voltage, and
wherein the second sub-circuit comprises:
a first transistor having one end connected to the power supply voltage and the other end connected to the second node; and
a second transistor controlled by the power supply voltage and having one end connected to a gate of the first transistor and the other end connected to the pad.

2. The fail-safe input/output circuit of claim 1, wherein the one end of the first transistor is connected to the power supply voltage via a floating well, and
a gate of the second transistor is connected to the power supply voltage via the floating well.

3. The fail-safe input/output circuit of claim 2, wherein the first drive node, the floating well, and the pad are at the same voltage when the power supply voltage is off.

4. The fail-safe input/output circuit of claim 2, wherein the floating well is connected to a floating well control circuit, and
wherein the floating well control circuit:
causes a voltage of the pad to be applied to the floating well when the power supply voltage is off, and
causes the power supply voltage to be applied to the floating well when the power supply voltage is on.

5. The fail-safe input/output circuit of claim 4, wherein the floating well control circuit comprises:
a first floating well transistor having one end connected to the power supply voltage and the other end connected to the floating well;
a second floating well transistor having one end connected to the floating well and the other end connected to the pad;
a third floating well transistor having one end connected to a gate of the first floating well transistor via a floating well node and the other end connected to a ground voltage; and
a fourth floating well transistor having one end connected to the gate of the first floating well transistor via the floating well node and the other end connected to the pad, and
wherein a gate of the third floating well transistor is connected to the power supply voltage,
a gate of the fourth floating well transistor is connected to the power supply voltage via the floating well, and
a floating well control signal is output via the floating well node.

6. The fail-safe input/output circuit of claim 5, further comprising:
a second control circuit, which is connected to a second drive node different from the first drive node of the pad drive circuit and into which the control signal is input,
wherein the second control circuit applies a ground voltage to the second drive node when the power supply voltage is off.

7. The fail-safe input/output circuit of claim 1, wherein the second sub-circuit further comprises a third transistor controlled by the power supply voltage and having one end connected to the one end of the second transistor.

8. The fail-safe input/output circuit of claim 1, wherein the pad drive circuit comprises:
a fourth transistor having one end connected to the power supply voltage and including a gate connected to the first drive node;
a fifth transistor controlled by the power supply voltage and having one end connected to the first drive node and the other end connected to the pad; and
a sixth transistor having one end connected to the other end of the fourth transistor.

9. The fail-safe input/output circuit of claim 1, wherein the first control circuit further comprises a third sub-circuit connected to the first sub-circuit and controlled by the power supply voltage,
the first sub-circuit comprises a seventh transistor having one end connected to the first node,
the third sub-circuit is connected to a gate of the seventh transistor, and
the seventh transistor is turned off by the third sub-circuit when the power supply voltage is off.

10. The fail-safe input/output circuit of claim 1, further comprising:
a second control circuit connected to a second drive node different from the first drive node of the pad drive circuit,
wherein the second control circuit applies a ground voltage to the second drive node when the power supply voltage is off.
